(19) United States
(12) Patent Application Publication
(10) Pub. No.: US 2016/0122590 A1
(43) Pub. Date: May 5, 2016

(54) Chemical Mechanical Polishing Slurry for Reducing Corrosion and Method of Use Therefor

(71) Applicant: AIR PRODUCTS AND CHEMICALS, INC., Allentown, PA (US)

(72) Inventors: Blake J. Lew, Scottsdale, AZ (US); Krishna P. Murella, Phoenix, AZ (US); Malcolm Grief, Phoenix, AZ (US); Xiaobo Shi, Chandler, AZ (US); Dnyanesh Chandrakant Tamboli, Breinigsville, PA (US); Mark Leonard O'Neill, Queen Creek, AZ (US)

(73) Assignee: AIR PRODUCTS AND CHEMICALS, INC., Allentown, PA (US)

(21) Appl. No.: 14/884,104

(22) Filed: Oct. 15, 2015

Related U.S. Application Data
(60) Provisional application No. 62/073,636, filed on Oct. 31, 2014.

(51) Int. Cl. C09G 1/02; H01L 21/67; B24B 37/14; H01L 21/306

(52) U.S. Cl. CPC C09G 1/02; H01L 21/30625; H01L 21/67075; B24B 37/14

(57) ABSTRACT

Slurries and associated methods and systems for the chemical mechanical planarization (CMP) of tungsten-containing films on semiconductor wafers are described. The slurries comprise abrasive particles, activator-containing particles, peroxygen oxidizer, pH adjustor, and the remaining being water. The slurries have a pH in the range of 4 to 10; preferably 5 to 9; more preferably 6 to 8.

### CROSS REFERENCE TO RELATED PATENT APPLICATIONS

The present patent application claims the benefit of U.S. Provisional Patent Application Ser. No. 62/073,636filed Oct. 31, 2014.

### BACKGROUND OF THE INVENTION

This invention pertains to slurries, methods and systems used for metal, specifically, tungsten chemical mechanical planarization (CMP).

Integrated circuits are interconnected through the use of well-known multilevel interconnections. Interconnection structures normally have a first layer of metallization, an interconnection layer, a second level of metallization, and typically third and subsequent levels of metallization. Interlevel dielectric materials such as silicon dioxide and sometimes low-k materials are used to electrically isolate the different levels of metallization in a silicon substrate or well. The electrical connections between different interconnection levels are made through the use of metallized vias and in particular tungsten vias. U.S. Pat. No. 4,789,648 describes a method for preparing multiple metallized layers and metallized vias in insulator films. In a similar manner, metal contacts are used to form electrical connections between interconnection levels and devices formed in a well. The metal vias and contacts are generally filled with tungsten and generally employ an adhesion layer such as titanium nitride (TiN) and/or titanium to adhere a metal layer such as a tungsten metal layer to the dielectric material.

In one semiconductor manufacturing process, metallized vias or contacts are formed by a blanket tungsten deposition followed by a CMP step. In a typical process, via holes are etched through the interlevel dielectric (ILD) to interconnection lines or to a semiconductor substrate comprising semiconductor devices. Next, a thin adhesion layer such as titanium nitride and/or titanium is generally formed over the ILD and is directed into the etched via hole. Then, a tungsten film is blanket deposited over the adhesion layer and into the via. The deposition is continued until the via hole is filled with tungsten. Finally, the excess tungsten is removed by chemical mechanical polishing (CMP) to form metal vias. Similar processes can be used to form other pattern structures.

In another semiconductor manufacturing process, tungsten is used as a gate electrode material in the transistor because of its superior electrical characteristics over poly-silicon which has been traditionally used as gate electrode material. (A. Yagishita et al, IEEE TRANSACTIONS ON ELECTRON DEVICES, VOL. 47, NO. 5, MAY 2000)

In another semiconductor manufacturing process, tungsten is used to fill vias to form devices with three dimensional (3D) interconnect structures.

In a typical CMP process, the substrate is placed in direct contact with a rotating polishing pad. A carrier applies pressure against the backside of the substrate. During the polishing process, the pad and table are rotated while a downward force is maintained against the substrate back. An abrasive and chemically reactive solution, commonly referred to as a “slurry” is deposited onto the pad during polishing, where rotation and/or movement of the pad relative to the wafer brings said slurry into the space between the polishing pad and the substrate surface. The slurry initiates the polishing process by chemically reacting with the film being polished. The polishing process is facilitated by the rotational movement of the pad relative to the substrate as slurry is provided to the wafer/pad interface. Polishing is continued in this manner until the desired film on the insulator is removed.

The generally understood mechanism of tungsten CMP is tungsten oxide layer would form on the surface under the oxidizing conditions on the CMP. A combination of mechanical abrasion of the softer oxide layer and chemical dissolution of oxides or the exposed tungsten allows tungsten to be polished at high removal rates. (Kaufman F. B. et al. J. Electrochem. Soc. 1991 138:3460-3465). Formation of a stable tungsten oxide layer (WO₃) is often considered necessary to ensure planar surface. It is believed that slurries which do not form passivating oxide on the surface, allow chemical etching of tungsten which limits the ability of the polishing process to planarize the surface. Slurry that chemically etches the metal surface may yield high number of corrosion defects. Corrosion could be especially worse if for some reason there is CMP tool failure and the wafer is exposed to the slurry for longer times

Kaufman and the references cited within teach that in the absence of complexation reagents or substances which form insoluble salts, pH less than 4 is required to form stable, passive WO₃. Presence of an oxidant such as K₃Fe(CN)₆ and weak organic base complexing agents is needed to extend the range of pH in which W gets passivated to pH 6.5

Tamboli et al. (Electrochemical Society Proceedings, 2000-26, p. 212-221) show that the passivity of tungsten is most optimal at pH 2. Passivation current density increases almost exponentially with pH. This result indicates poor passivity and chemical dissolution with increasing pH.

Kneer et al. (J. Electrochem. Soc., Vol. 143, No. 12, December 1996 p. 3095-4100) also show that the passive tungsten oxide layer at pH 2 is thicker compared to using X-ray Photoelectron Spectroscopy and electrochemical measurements.

It is evident from this prior art that the near neutral pH would not be suitable for formulating the slurry so as to take advantage of the passive oxide formation.

Many tungsten slurries also use catalysts to improve the oxidation kinetics of peroxygen oxidizers (those containing —O—O—) bonds. Some of the catalysts that are useful for tungsten CMP are described in U.S. Pat. No. 5,958,288. They comprise soluble multivalent metal containing species. Catalysts are believed to increase the oxidation abilities of the slurry by forming hydroxyl radicals by a reaction called Fenton reaction. Hydroxyl radicals are far more potent oxidants compared to hydrogen peroxide. As a result they increase the tungsten removal rates in slurries even when the catalyst is present in concentrations less than 100 ppm. Most commonly used catalyst in tungsten slurries is ferric nitrate.

Kang Y. W and Hwang K-Y, Water Research, Volume 34, Issue 10, 1 July 2000, Pages 2786-2790 and the references cited within, clearly teach that Fenton reaction efficiency is rapidly decreased with increasing pH reaction in the range of 4-7. The loss of efficiency is attributable by loss of stability of hydrogen peroxide. In a pH reaction higher than 5, the oxidation efficiency is rapidly decreased, not only by decomposition of hydrogen peroxide, but also by deactivation of a ferrous catalyst with the formation of ferric hydroxide complexes.

Another issue with the use of soluble catalysts is stability. In near neutral pH, metal catalysts may form insoluble hydroxides and precipitate out. This is undesirable as it will change the performance of the slurry over time. Colloidal stability of colloidal silica slurries is poor in near-neutral pH. Some multi-valent soluble metal catalysts can have deleterious effect on the colloidal stability of slurry in near neutral pH.

Clearly it would not be obvious to use pH>4 in tungsten slurries if the objective is to use a catalyst to enhance removal rates of tungsten through Fenton reaction.

Furthermore, there are issues with current tungsten slurries which use soluble catalysts is corrosion. Corrosion is likely induced by high potency hydroxyl radicals. There are many types of corrosion inhibitors proposed to control the corrosion in various patents e.g. U.S. Pat. No. 6,083,419, U.S. Pat. No. 6,136,711, U.S. Pat. No. 7,247,567, U.S. Pat. No. 7,582,127. However, use of corrosion inhibitors may introduce different sets of challenges such as defectivity, non-uniformity in performance.

There is still a need for CMP slurries for tungsten polishing that do not need any added on corrosion inhibitors to reduce corrosion while offer high tungsten removal rates and low tungsten static etch rate.

### BRIEF SUMMARY OF THE INVENTION

This invention discloses chemical mechanical planarization (CMP) slurries for tungsten polishing that offer high tungsten removal rates while with low tungsten static etch rate. The CMP slurries have a near neutral pH.

In one aspect, the invention provides a chemical mechanical planarization (CMP) slurry for tungsten polishing comprising:

abrasive,

activator-containing particles,

peroxygen oxidizer,

a pH adjustor; and

remaining being water;

wherein the tungsten CMP slurry has a pH in the range of 4 to 10, preferably 5 to 9, more preferably 6 to 8.

In another aspect, the invention provides a method for chemical mechanical planarization of a semiconductor substrate comprising at least one surface having tungsten, comprising the steps of:
a) contacting tungsten with a polishing pad;
b) delivering a polishing slurry to the at least one surface having tungsten, the polishing slurry comprising:
   abrasive;
   activator-containing particles;
   peroxygen oxidizer;
   pH adjustor; and
   the remaining being water;
   wherein the polishing slurry has a pH in the range of 4 to 10, preferably 5 to 9, more preferably 6 to 8;
and
C) polishing the at least one surface having tungsten with the polishing slurry.

In yet another embodiment, described herein is a system for chemical mechanical planarization (CMP), comprising:
a semiconductor substrate comprising at least one surface having tungsten;
a polishing pad; and
a polishing slurry comprising:
   abrasive;
   activator-containing particles;
   peroxygen oxidizer;
   pH adjustor; and
   the remaining being water;
   wherein the polishing slurry has a pH in the range of 4 to 10, preferably 5 to 9, more preferably 6 to 8;
and
wherein the at least one surface having tungsten is in contact with the polishing pad and the polishing slurry.

The abrasive is selected from the group consisting of silica, alumina, zirconium oxide, ceria, polymers, mixed oxide particles, ceria coated silica particles, aluminum doped silica particles, and combinations thereof. The activator-containing particles are particles containing activators. The particles are selected from the group consisting of silica, alumina, zirconium oxide, ceria, polymers, mixed oxide particles, ceria coated silica particles, aluminum doped silica particles, and combinations thereof. The activators are metal-containing compounds having the metal selected from periodic table groups 1(b), 2(b), 3(b), 4(b), 5(b), 6(b), 7(b), and 8(b); preferably compounds of metals of group 1(b), group 8(b) and combinations thereof; more preferably compounds of iron, copper, cerium, nickel, manganese, cobalt, and combinations; most preferably compounds of iron, cerium salts, and combinations thereof. The pH adjuster is selected from the group consisting of acid, base, amine, and combinations thereof; preferably ammonium hydroxide, quaternary ammonium hydroxides, potassium hydroxide, nitric acid, phosphoric acid, sulfuric acid, and combinations thereof.

The slurries may comprise promoters, chelating agents, corrosion inhibitors, organic and/or inorganic acids, pH buffers, oxidizer stabilizers, passivating agents, surfactants, dispersants, polymers, biological preservatives, removal rate selectivity adjustors, film-forming anticorrosion agents, and polish enhancement agents.

### DETAILED DESCRIPTION OF THE INVENTION

This invention pertains to slurries that can be used in chemical mechanical planarization of metal such as tungsten containing films. While current understanding of the tungsten electrochemisty suggests that the corrosion of tungsten is worse for near neutral pH slurries compared to acidic slurries, unexpected findings in this inventions allow slurries with lower corrosion propersity in near neutral pH compared to acidic pH. Formulations or slurries of this invention provide unique and unexpected combination of results including (1) high tungsten removal rates with very low static etch rates; (2) low pattern erosion even at high polishing down force; (3) ability to form highly concentrated slurry formulations (>5×), which can be custom diluted at the customer operations; (4) ability to increase tungsten removal rates with increase in oxidizer concentration without increase in the static etch rates of the solutions; (5) low surface roughness; (6) Lower corrosion defects such as seam attack or key holes; (7) increased tolerance to process excursions such as tool failures; and (8) improved process stability.

Removal of tungsten in the CMP is believed to be due to synergy between mechanical abrasion and tungsten oxidation followed by dissolution. The CMP slurry that satisfies the need comprises an abrasive, one or more oxidizers that produce free radicals, activator-containing particles that help generate the radicals, and one or more pH adjusting agents to have pH between 4 to 10; preferably 5 to 9, more preferably 6 to 8.

Optional additives such as promoters; chelating agents, corrosion inhibitors, organic and/or inorganic acids, pH buffers, oxidizer stabilizers, passivating agents, surfactants, dispersants, polymers, biological preservatives, removal rate selectivity adjustors, film-forming anticorrosion agents; and polish enhancement agents, are generally employed in the CMP slurries to facilitate or promote stabilization of the slurry against settling, flocculation (including precipitation, aggregation or agglomeration of particles, and the like), and decomposition.

### Abrasive Particles

The CMP slurry of the present invention comprises one or more of various abrasives.

Various types of abrasives have been reported that can be used in CMP slurries. These include any suitable abrasive, e.g., fumed or colloidal silica, alumina, gamma alumina, ceria, abrasive plastic or polymeric particles, spinels, zinc oxide, hybrid organic/inorganic particle (e.g., silicone particles such as Tospearl™, Toshiba Silicone Co., Ltd., Tokyo, Japan), coated abrasive particles comprising of a core and a shell made up of different materials wherein the shell may be continuous or discontinuous, or mixtures thereof. Silica abrasives (colloidal and fumed) are most common types of abrasives used in tungsten. CMP. In some embodiments, the abrasive particles may also be doped with another metal oxide in the lattice. An example includes silica particle doped with alumina.

The abrasive is generally in the form of an abrasive particle, and typically many abrasive particles, of one material or a combination of different materials. The morphology of the particles can be spherical, cocoon shaped, aggregate comprising smaller particles, or any other morphology suitable for polishing purposes. Generally, a suitable abrasive particle is more or less spherical and has an effective diameter of about 30 to about 300 nanometers (nm), although individual particle size may vary. Abrasive in the form of aggregated or agglomerated particles are preferably processed further to form individual abrasive particles. A slurry may have more than one type of abrasive, and it may also be advantageous to have different sizes for different types of abrasives.

A suitable metal oxide abrasive can be a metal oxide or metalloid oxide or a chemical mixture of metal oxides or metalloid oxides. Suitable metal oxide abrasive includes, but is not limited to, alumina, ceria, germania, silica, spinel, titania, an oxide or nitride of tungsten, zirconia, or any of the above doped with one or more other minerals or elements, and any combination thereof. The metal oxide abrasive may be produced by any of a variety of techniques, including sol-gel, hydrothermal, hydrolytic, plasma, pyrogenic, aerogel, fuming and precipitation techniques, and any combination thereof.

Precipitated metal oxides and metalloid oxides can be obtained by known processes by reaction of metal salts and acids or other precipitating agents. Pyrogenic metal oxide and/or metalloid oxide particles are obtained by hydrolysis of a suitable, vaporizable starting material in an oxygen/hydrogen flame. An example is pyrogenic silicon dioxide from silicon tetrachloride. The pyrogenic oxides of aluminum oxide, titanium oxide, zirconium oxide, silicon dioxide, cerium oxide, germanium oxide and vanadium oxide and chemical and physical mixtures thereof are suitable.

The abrasive may be a mixed oxide such as consisting of the two molecular species SiO₂ and Al₂O₃. Abrasives comprising alumina coated silica can also be useful.

In one preferred embodiment, the metal oxide abrasive is a precipitated or fumed abrasive, and preferably a fumed abrasive. By way of example, a fumed metal oxide abrasive may be a fumed silica or fumed alumina or a fumed silica/alumina.

Silica is the preferred abrasive. The silica can be any of precipitated silica, fumed silica, silica fumed, pyrogenic silica, silica doped with one or more adjutants, or any other silica-based compound. In an alternate embodiment the silica can be produced, for example, by a process selected from the group consisting of a sol-gel process, a hydrothermal process, a plasma process, a fuming process, a precipitation process, and any combination thereof. The silica in one embodiment is advantageously at a particle size between about 2 and about 300 nanometers, for example between about 30 and about 250 nanometers.

Particles with mean particle size larger than 100 nm, or preferably more than 150 nm are preferred as they would provide very high tungsten removal rates in CMP at the same abrasive particle concentration in terms of wt %. Very large particle such as those with size greater than 300 nm may pose other challenges such as particle stability and scratching.

Abrasive particles may be purified using suitable method such as ion exchange to remove metal impurities that may help improve the colloidal stability. Alternatively high purity abrasive particles that are manufactured from precursors other than metal silicates can be used.

In general, the above-mentioned abrasives may be used either alone or in combination with one another. Two or more abrasive particles with different sizes may also be combined to obtain excellent performance.

The abrasive concentration in the slurry can range from 0.0 to 20 wt %, while the more preferably from about 0.05 to 5 wt %, more preferably 0.1 to 2 wt %, relative to the slurry.

### Oxidizer

The CMP slurry of the present invention comprises one or more of various oxidizers for chemical etching of material.

Various oxidizing agents such as periodic acid, periodate salts, perbromic acid, perbromate salts, perchloric acid, perchloric salts, perboric acid, and perborate salts and permanganates, as well as bromates, chlorates, chromates, iodates, iodic acid, and cerium (IV) compounds have been reported in literature. Hydrogen peroxide, iodic acid or its salts, and periodic acid or its salts are known to be most commonly used oxidizers in tungsten CMP.

The oxidizing agent of the CMP slurry contacts the substrate, and assists in the chemical removal of targeted material on the substrate surface. The oxidizing agent component is thus believed to enhance or increase the material removal rate of the slurry. Preferably, the amount of oxidizing agent in the slurry is sufficient to assist the chemical removal process, while being as low as possible to minimize handling, environmental, or similar or related issues, such as cost.

Advantageously, in one embodiment of this invention, the oxidizer is a component which will, upon exposure to at least one activator, produce free radicals giving an increased etching rate on at least selected structures. The free radicals described infra will oxidize most metals, and will make the surface more susceptible to oxidation from other oxidizers. However, oxidizers are listed separately from the “Compound Producing Free Radicals”, to be discussed infra, because some oxidizers do not readily form free radicals when exposed to the activators, and in some embodiments it is advantageous to have one or more oxidizers which provide matched etching or preferential etching rates on a variety of combinations of metals which may be found on a substrate.

As is known in the art, some oxidizers are better suited for certain components than for other components. In some embodiments of this invention, the selectivity of the CMP system to one metal as opposed to another metal is maximized, as is known in the art. However, in certain embodiments of this invention, the combination of oxidizers is selected to provide substantially similar CMP rates (as opposed to simple etching rates) for a conductor and a barrier combination, so that in many cases acceptable planarization is achieved by a single CMP slurry.

The oxidizing agent is in one embodiment an inorganic or organic peroxygen-compound. A peroxygen-compound is generally defined as a compound containing an element in its highest state of oxidation, such as perchloric acid; or a compound containing at least one peroxy group (—O—O—), such as peracetic acid and perchromic acid.

Suitable peroxygen-compounds containing at least one peroxy group include, but are not limited to, peracetic acid or salt thereof, a percarbonate, and an organic peroxide, such as benzoyl peroxide, urea hydrogen peroxide, and/or di-t-butyl peroxide.

Suitable peroxygen-compounds containing at least one peroxy group include peroxides. As used herein, the term “peroxides” encompasses R—O—O—R′, where R and R′ are each independently H, a C₁ to C₆ straight or branched alkyl, alkanol, carboxylyic acid, ketone (for example), or amine, and each of the above can independently be substituted with one or more benzyl group (for example benzoyl peroxide) which may themselves be substituted with OH or C1-C5 alkyls, and salts and adducts thereof. This term therefore includes common examples such as hydrogen peroxide, hydrohydrogen peroxide, peroxyformic acid, peracetic acid, propaneperoxoic acid, substituted or unsubstituted butaneperoxoic acid, hydroperoxy-acetaldehyde, Also encompassed in this term are common complexes of peroxides, for example urea peroxide.

Suitable peroxygen-compounds containing at least one peroxy group include persulfates. As used herein, the term “persulfates” encompasses monopersulfates, di-persulfates, and acids and salts and adducts thereof. Included for example is peroxydisulfates, peroxymonosulf uric acid and/or peroxymonosulfates, Caro's acid, including for example a salt such as potassium peroxymonosulfate, but preferably a non-metallic salt such as ammonium peroxymonosulfate.

Suitable peroxygen-compounds containing at least one peroxy group include perphosphates, defined as above and including peroxydiphosphates.

Also, ozone is a suitable oxidizing agent either alone or in combination with one or more other suitable oxidizing agents.

Suitable per-compounds that do not contain a peroxy group include, but are not limited to, periodic acid and/or any periodiate salt (hereafter “periodates”), perchloric acid and/or any perchlorate salt (hereafter “perchlorates”) perbromic acid and/or any perbromate salt (hereafter “perbromates”), and perboric acid and/or any perborate salt (hereafter “perbromates”).

Other oxidizing agents, such as Iodates are also suitable components of the slurry of the present invention.

Two and more oxidizers may also be combined to obtain synergistic performance benefits.

The oxidizer concentration can range from 0.0 to 30% while the more preferred amount of oxidizing agents is from about 0.5 to about 10 weight percent relative to the slurry, for example between about 1% and about 8% of oxidizer.

### Promoters

In some embodiments, compounds of Al, Ag, Ce, Co, Cr, Cu, Fe, Mo, Mn, Nb, Nd, Ni, Os, Pd, Pt, Rh, Ru, Sc, Sm, Ta, Ti, V, or W in minor amounts dissolved in the solution are useful. These are believed to facilitate the action of the oxidizers, as discussed in U.S. Pat. No. 5,958,288, the disclosure of which is incorporated herein by reference. Metal ions in solution are believed to act as oxidizers with a degree of affinity to the substrate, particularly to metal substrates. If they are able to be oxidized by other oxidizers in the fluid, there will be some synergistic action between the two. In most cases the promoters are believed not to facilitate the action of the free radicals, however. Compounds that form promoters on exposure to a catalyst or substrate, such as those compounds described in U.S. Pat. No. 5,863,838, the disclosure of which is incorporated by reference, are also useful.

In some embodiments of the present invention, the fluid slurry contacting the substrate has a small amount of metal ion oxidizers, herein called promoters. Soluble compounds or salts of copper, aluminum, cerium, and iron are used as oxidizers or promoters in CMP solutions. If used, a preferred metal-containing oxidizer promoter is soluble cerium salts or aluminum salts.

### Activator

The CMP slurry of the present invention comprises one or more of various activators, or more specifically, activator-containing particles.

The activator is a material that facilitates the formation of free radicals by at least one free radical-producing compounds present in the fluid.

A heterogeneous activator is a chemical specie which is physically bonded to a particle surface which is different chemically from the activator. In certain embodiments the activator can be dispersed inside the particle as well as on the particle surface. A homogeneous activator, on the other hand is a chemical specie which is chemically homogeneous.

Generally, light-activated activators such as titanium oxides (and light used as an activator) are not preferred. There is no method to get light at the desired concentration between a pad and a substrate. The activator must therefore be pre-activated, and/or the free radicals must be formed, before the fluid passes between a pad and a substrate.

In some configurations use of photo-activated activator is acceptable. For example, for long-lived free radicals, i.e., with an average life in solution of a tenth of a second or more, the photoactivator can be a matrix containing activator that the fluid must contact just before passing between a pad and a substrate. A bed of activator can for example be placed immediately upstream of the fluid outlet, so that free radicals formed have not totally degraded before passing between the pad and the substrate. The photoactivated materials of U.S. Pat. No. 6,362,104, the disclosure of which is incorporated by reference, can be used in this capacity. These include TiO₂ and Ti₂O₃, as well as to the less preferred oxides of Ta, W, V, and Nb.

The activator may be a non-metal-containing compound. Iodine is a useful with for example hydrogen peroxide to form free radicals. The iodine may be present in an amount sufficient to create the desired free radical activity. In some embodiments, the iodine may be present in an amount ranging from about 1 ppm to about 5000 ppm, preferably between about 10 ppm and about 1000 ppm. Non-metallic activators are often synergistically combined with metal-containing activators.

The activator can also be a metal-containing compound, in particular a metal selected from the group consisting of the metals known to activate a Fenton's Reaction process in hydrogen peroxide. Advantageously, most metal-containing activators are associated with a solid as discussed below. Of course, the system of this invention may optionally comprises both metal-containing activators and non-metal-containing activators, where the non-metal-containing activators are in solution in the fluid and where at least a portion of the metal-containing activators are associated with a solid.

In another embodiment, the activator is any metal-containing compound known to be useful in Fenton's reactions as an activator, wherein the oxidizer is a peroxide, particularly hydrogen peroxide. Transition metals like copper, manganese, cobalt, and cerium, as well as the more traditional iron and copper, are able to catalyze this reaction. However, these metals having multiple oxidation states, particularly iron and copper, are known to be particularly problematic if in solution with for example hydrogen peroxide or persulfates. Further, cobalt, manganese, and cerium in solution have environmental concerns. All are a contaminant to the substrate. Finally, all, if in solution, are believed to act as promoters rather than activators. We have found, however, that if these elements or molecules are associated with a solid contacting the fluid, they can function as activators.

In one important embodiment, the activator comprises a metal-containing compound having the metal other than a metal of Group 4(b), Group 5(b) or Group 6(b) of the Periodic Table of Elements. In one embodiment, compounds of metals of Group 1(b) or Group 8(b) are preferred metal-containing activators.

In another important embodiment, the activator comprises any transition metal-containing compound that can react with a compound that produces free radicals, is associated with a solid. That is, the activators of the present invention are not soluble in the fluid. Activators can be associated with a particle. The particle may be an abrasive, or it may be a carrier for the activator. Activators can be associated with a pad. Activators can be held in a matrix such that the fluid containing the compounds that form free radicals contacts the activator immediately before contacting the substrate.

Preferably, the activator can function effectively without actinic radiation, and the oxidizer itself can rejuvenate the activator. This step in some very preferred embodiments will also result in the formation of a second free radical, though often a weaker free radical than was produced in the first step. For example, without being bound to theory, as opposed to the classical Fenton's reaction which is the oxidation of Fe(II) by hydrogen peroxide, the reaction of the surface bound Fe activator of this system by hydrogen peroxide forms both superoxide anion and hydroxyl radicals. Therefore, hydrogen peroxide is both an oxidant and reductant in these systems.

If an activator is itself made effective with light, the “effectiveness” of the activator will decay when it is not exposed to light. It is very difficult to get light between a pad and a substrate, and therefore concentration gradients will occur.

Generally, the preferred activators are iron, copper, cerium, nickel, manganese, and/or cobalt. They can be used in any combination. The more preferred activators are iron or cerium salts.

It is advantageous that the activator be associated with a surface, as opposed to being for example a solid crystal. The activator can be a homogeneous composition of the active activator. The homogenous activator are preferably small particles with high surface areas. This form of activator should have a mean particle diameter less than about 1 micron, preferably less than 0.4 microns, more preferably less than 0.1 microns, and a surface area greater that about 10 m²/g. The same preferred particle characteristics will also optimize the colloidal stability of the activator in the polishing slurries.

Solid crystals of activator-type material often do not have sufficient binding capacity/flexibility in the binding of the atoms to allow the activator components to change oxidation states to react with the compound that produces free radicals. Interaction of crystals may result in crystal dissolution, as the metal leaves the crystal and enters the solution. For this reason solid activator material is generally discouraged, though if metal loss is insignificant solid activator particles can be contemplated.

The metal-containing activator compounds associated with a particle or a pad may be in a variety of forms, such as an oxide, a nitrate, a halide, a perchlorate, or an acetate of the metal. The counter-ions are generally of lesser significance, unless they stabilize the activator by hindering access to the compounds that form free radicals. In one embodiment, the activator associated with a particle and/or polishing pad is a metal-containing acetate, such as copper acetate (“CuAc”) or iron acetate (“FeAc”) or cerium acetate (“CeAc”). The metal-containing activator compounds may be a source of ions associated with a solid and not dissolved in the fluid containing the oxidizer

The activators of the present invention can include iron and copper oxides. The activator is preferably chemically or physically associated with the surface of a particle as molecular species, as a small particle or as a monolayer. For example, a doped Ceria-gamma Alumina Supported Nickel is a useful activator for some compounds that form free radicals. The activator activity of an alumina supported copper oxide, compared to that of goethite, has shown that the supported copper oxide was approximately ten times more active than goethite. For traditional Fenton's reactions, Fe containing zeolite when compared with the behavior of homogeneous Fe activators at the same experimental conditions found the heterogeneous activators have a higher reactivity and a reduced dependence on the pH of the solution. However, under some conditions they can also have a higher rate of the side reaction of hydrogen peroxide decomposition to water and oxygen.

The abrasive can be a co-formed abrasive in which the activator is homogeneously mixed with another oxide to form solid particles containing an intimate mixture of the activator supported on metal oxide. In addition the activator can be chemically or physically adsorbed on the surface of the abrasive as molecular species, small particles or as a monolayer.

The activator-containing particles are particles containing activators. In most embodiments of the invention, however, the transition-metal-containing-activator is associated with an abrasive particle, thus, forming activator-containing particles. The particles are selected from the group consisting of silica, alumina, zirconium oxide, ceria, polymers, mixed oxide particles, ceria coated silica particles, aluminum doped silica particles, and combinations thereof. The activators are metal-containing compound having the metal selected from periodic table groups 1(b), 2(b), 3(b), 4(b), 5(b), 6(b), 7(b), and 8(b); preferably compounds of metals of group 1(b), group 8(b) and combinations thereof; more preferably compounds of iron, copper, cerium, nickel, manganese, cobalt, and combinations, most preferably compounds of iron, cerium salts, and combinations thereof.

The amount of activator in a slurry can be low. The activator associated with particles in a slurry can be present in any activating amount, for example, from about 0.0005 wt % (5ppm) to about 10 wt %. High concentrations are usually wasteful, however. In a system with transition metal containing activator, i.e., a slurry having a transition metal activator coated on solid particles contained within the slurry, excellent free radical activity is observed if the amount of activator in the slurry is about 0.1 to 2000 ppm total activator. If the activator is located on particles such that access to fluid is not impaired, a slurry can have between about 1 to 1000 ppm, for example between about 2 to100 ppm. In preferred low-activator-content slurries tested, activator concentrations of between about 1 to about 100 ppm, for example between about 5 to about 50 ppm, for instance about 15 ppm, of activator expressed as a weight percent of the slurry, provided accelerated CMP removal rates compared to slurries without activator.

Compounds or salts that might otherwise be considered an activator are not included if they do not function as an activator. As used herein, therefore, a transition metal is an activator only if it is associated with a solid. For example, activator within a particle matrix where it cannot generate free radicals that can escape the particle structure is not included in the term activator. Activator elements or compounds that cannot activate the formation of free radicals, for example because it is incorporated within a matrix where changes between oxidation states is discouraged, is not included as activator. Compounds that can plate out or contaminate the substrate are viewed as contaminants. Finally, activator that is chelated or otherwise not available for reaction with the compound that produces free radicals is not included as activator.

In one important embodiment of the invention, at least a portion of the activator is associated with at least a portion of the abrasive particles. In its most general meaning, the term “associated” means that activator compounds are affixed to the surface of an abrasive particle, such that the activator contacts the fluid containing the Free Radical-Producing Compound, wherein the contacting results in significant increase in free radical formation (as determined by significant increase in CMP removal rates discussed previously). Generally, having the activator be associated with the abrasive means the activator is coated on the abrasive, absorbed onto the abrasive, or is adsorbed on to the abrasive, or is otherwise attached or bound to the abrasive. The activator coating can be in a pure form, or the activator can be admixed with other compounds, minerals, metals, and the like, to form an activator composition that is coated onto at least a portion of an abrasive.

In preferred embodiments very little, preferably none, of the activator breaks the association with the abrasive and enters the solution as an ion or soluble compound, or plates onto the substrate. Therefore, the abrasive with the associated activator may be stabilized. For example, the abrasive with the associated activator may be calcined. The abrasive with the associated activator may be subsequently covered with or treated with other compounds including stabilizers, surfactants, silanes, or other components. Or, the abrasive with the associated activator may be covered with or treated with other compounds and calcined.

A system with iron activator, i.e., a slurry having iron coated on solid particles contained within the slurry, shows excellent free radical activity if the amount of activator iron is about 2 to 1000 ppm total activator iron, preferably 3 to 500 ppm total activator iron, and for low iron embodiments about 4 to 200 ppm total activator iron. Iron that is not contacting the fluid, including iron for example within a particle matrix where it cannot generate free radicals that can escape the particle structure, is not included in the term activator iron. Iron that cannot activate the formation of free radicals, for example because it is incorporated within a matrix where changes between oxidation states is discouraged, is not included in activator iron. Finally, iron that is chelated or otherwise not available for reaction with the compound that produces free radicals is not included as activator iron. An exemplary slurry has about 50 ppm to about 300 ppm total activator iron, most of it absorbed, adsorbed, or coated onto the abrasive.

In low-metal-containing-activator embodiments, less than 80 ppm total metal-containing activator in a slurry can be used. This activator may act alone, or be supplemented with for example activator on the pad and/or non-metal-containing activator in the fluid. In preferred low-metal-containing-activator embodiments, less than 40 ppm total metal-containing activator in a slurry can be used, for example between about 5 ppm and about 30 ppm, or about 5 ppm to 20 ppm. Of course, the limits on the metal content of the fluid contacting the substrate and having the compound producing the free radical and optionally other oxidizers is still important. It is highly beneficial, even when the slurry contains up to 500 ppm of activator associated with particles, to have for example less than 20 ppm, preferably less than 8 ppm, for example less than 4 ppm, of these metals in solution in the fluid contacting the substrate.

An activator associated with an abrasive means the activator is not in solution in the slurry. Metals in solution act as promoters and will therefore contaminate a substrate. Further, if chemical reactions occur to cause the activator to tend to plate out (i.e., be reduced to a metallic state), the activator will still not move from the surface of the abrasive, and therefore will not plate out on the substrate. Additionally, we have surprisingly found that activator associated with an abrasive has a much lower tendency to spontaneously decompose certain oxidants, for example hydrogen peroxide, even at higher pH values where hydrogen decomposition by metal ions in solution is known. While not being bound by theory, generally, an activator associated with an abrasive is believed to only incidentally contact the substrate.

When the activator is associated with an abrasive particle, activator-containing particles concentration can range from 0.01 to 5 wt %, or between 0.05 to 1 wt %, or preferably between 0.1-0.5 wt %.

Copper is a known Fenton's agent, and therefore copper associated with solids makes an excellent activator. As copper can shift from a cuprous and cupric oxidation states, there will always be two bonding sites whereby the copper may be associated with the active sites on the abrasive material. The copper can be associated with the abrasive in the form of a salt, for example a cupric salt, a cuprous salt, in some forms a copper oxide, and in some forms metallic metal. Generally, metallic metal will be transformed to the cupric or cuprous form in the presence of oxidizers.

Silver is a useful activator for many systems, and can be coated onto for example silica, ceria, alumina, and other known abrasives, but if silver changes oxidation states, it may under some conditions become un-associated from the solid material. Additionally, the cost of silver is prohibitive unless recovery/recycle systems are in place. Finally, silver ions can complicate disposal of used slurry.

While gold coated onto one or more abrasives may be a useful activator for many systems, unless there is rigorous recovery and recycling of the activator-coated particles, the material cost will be too great for most commercial operations. On the other hand, gold may facilitate the production of free radicals without itself changing oxidation states. The same can be said for platinum and palladium coated onto a solid.

Coated or doped noble metals (Au, Ag, Re, Ru, Rh, Pd, Os, Ir, Pt) are as a rule present in elemental form or also have oxidic surface regions.

Iron associated with an abrasive is particularly useful and is the most preferred activator. Iron associated with silica is the most preferred system. The silica, with its numerous OH groups, can multiply bind with the iron, holding the iron firmly associated with the silica by a number of covalent and/or ionic type bonds. Yet, the plurality of bonds of iron onto the silica, be it absorbed, adsorbed, or coated, allows easy transformation between oxidation states without the iron having a tendency to dis-associate from the silica surface. Surprisingly, iron associated with silica can be used at high pH values, for example from pH 5 to pH 7 and in some cases up to pH 8. It is known that soluble iron at these pH values forms undesirable precipitates which contaminate substrate and which catalyze degradation of hydrogen peroxide into oxygen and water, resulting in unsafe explosive accumulations of gases.

The iron can be associated with the abrasive in the form of a salt, for example a ferric salt, a ferrous salt, in some forms a ferric oxide, and in some forms metallic metal. Generally, metallic metal will be transformed to the ferric or ferrous form in the presence of oxidizers. An additional advantage of iron is that it is environmentally benign and does not pose significant disposal problems.

Iron associated with alumina is also a useful abrasive/activator, as is iron associated with ceria. Iron associated with polymeric particles, or particles that have a polymeric component, are also useful.

Cerium salts, be they absorbed, adsorbed, or coated onto a solid, are also very useful abrasive/activators. Like iron, these ions can be strongly held by the active sites on the abrasive and/or particle, and once absorbed, adsorbed or coated, do not tend to become un-associated with the particle. Cerium salts can be used beneficially with for example iodine.

In another embodiment, metal-containing activator compounds comprising cobalt, copper, iron, cerium, or mixtures thereof are suitable activators.

Nickel, silver, or any combination thereof are suitable activators for some compounds which produce free radicals.

In another embodiment, metal-containing compounds having standard oxidization potential of from about −0.52 to about −0.25 eV are suitable activators. Examples of metal activators with oxidation potentials in this range include copper (−0.52 eV), iron (−0.44 eV), cobalt (−0.28 eV), and nickel (−0.25 eV). In another embodiment, formation of free radicals is promoted by an electric potential externally imposed across an activator/fluid system so the activator has an oxidation potential within this range.

Descriptions of redox systems involving activators that generate free radicals in the presence of oxidizing agents are provided in Walling, C., Free Radicals in Solution (1957), pp. 564-579, and Bacon, R, The Initiation of Polymerisation Processes by Redox Catalysts, Quart. Revs., Vol. IX (1955), pp. 287-310, the entire contents of which are incorporated herein by this reference. Such catalysts are candidate activators, and may be for example associated with the abrasive used in the slurry.

Compounds that do not need actinic radiation, for example UV radiation, to be effective as an activator are preferred activators. It is known that titanium oxides, when activated with actinic radiation, may form free radicals under certain conditions. This is not useful under CMP polishing conditions.

However, where the production of free radicals might be promoted where the production is acceptable without actinic radiation can be included. For example, formation of free radicals may promoted by actinic radiation for certain iron-based or a copper-based activators.

A preferred Group 8(b) metal is iron. A preferred Group 1(b) metal is copper.

Another preferred metal activator is cerium, a Group 3(b) activator. However, it is known that iron, copper, and cerium ions can cause metallic contamination of the substrate surface. Further, iron ions added as ferric nitrate to a hydrogen peroxide mixture was found to create undesirable degradation of the hydrogen peroxide and of the ferric ions. Other metallic ions have similar problems.

Surprisingly, the metal compounds, particularly the iron compounds, associated with an abrasive were found to have a large effect on the etching rate of a CMP slurry despite the fact that the iron ions largely did not contact the substrate, and did not cause direct oxidation of the substrate by taking electrons from the substrate, did not cause oxidation of the substrate by shuttling electrons from the oxidizer to the substrate. Rather, the iron compounds cause formation of free radicals, most preferably reactive oxygen radicals.

It is believed that the slurry of one important embodiment of the present invention is particularly advantageous by virtue of the interaction between at least one activator that is associated with a surface of a solid and at least free radical-forming compound, i.e., oxidizing agent that is in the fluid. That is, it is believed that a reaction takes place between the activator that is for example coated on an abrasive, and the oxidizing agent that is in the fluid, such as a peroxide or hydroperoxide, at the solid activator/liquid interface. It is believed that this reaction generates free radicals or active reaction intermediates, such as hydroxyl free radicals, at the activator surface, which favorably interact with the targeted material on the substrate when the free radicals contact the targeted substrate, which may be facilitated when the activator coating on the abrasive contacts the substrate surface.

The activator may include a metal-glycine complex, wherein the metal consists essentially of cerium, iron, manganese, cobalt, or mixture thereof.

Mixtures of activators can give increased activity. Cerium salts are particularly useful when admixed with iron or copper. Manganese salts are particularly useful when admixed with iron or copper. Rare earth metals may be useful when admixed with iron or copper. U.S. Pat. No. 5,097,071, the disclosure of which is incorporated herein by reference, teaches preparation process for an alumina supported copper useful for initiating Fenton's reaction, where the copper is impregnated with compounds of manganese and of one or more rare earth metals, having a Cu content of 0.1-5% by weight, a total content of compounds of manganese and of the rare earth metal or metals of 0.05 to 8% by weight, calculated as metals. The following may be mentioned as rare earth metals (subgroup III of the periodic table of elements): scandium, yttrium, lanthanum and the lanthanies. Yttrium, lanthanum, cerium, praseodymium, neodymium and dysprosium are preferred, cerium and lanthanum are particularly preferred and cerium is very particularly preferred.

In some embodiments, compounds of Ag, Cr, Mo, Mn, Nb, Nd, Os, Pd, Pt, Rh, Ru, Sc, Sm, Ta, Ti, V, or W which are associated with the surface of a particle which contains activator are useful. They may facilitate the action of the activators or with some compounds that form free radicals they may themselves become activators.

In some embodiments, for example when the abrasives or other particles having the activator associated with the surface are to be stored or handled, or when the activator makes a portion of the slurry unstable, the surface of the activator can be passivated. Passivating agents are beneficially relatively insoluble with respect to the bound activator (will not cause the activator to leave the particle) and also to have an affinity for the activator-coated particle. At selected pH values, selected carboxylic acid salts, for example oxalate, gallate, citrate, and the like can be made to coat the activator-containing particles. These passivators often can eliminate free radicals, which further enhances stability. Other passivators include succinates, benzoates, formates, cupferons, and 8-hydroxyquinoline. However, it is generally advisable to have the pH and or ionic conditions change prior to polishing so that the activator can be exposed and function.

Particles having the activator can be treated with various agents to enhance colloidal stability, including carboxylic acids and polycarboxylic acids.

### pH Adjustors

The CMP slurry of the present invention comprises one or more of various pH adjustors.

The pH of the slurry is desirably on the order of from about pH 5 to about pH 9, and preferably, from about pH 6 to about pH 8. The pH of the slurry may be adjusted using one or more of various pH adjustors, such as a suitable acid, base, amine, or any combination thereof. Preferably, a pH adjusting agent used in the slurry does not contain metal ions, such that undesirable metal components are not introduced into the slurry. Suitable pH adjusting agents include amines, ammonium hydroxide, nitric acid, phosphoric acid, sulfuric acid, organic acids, and/or salts thereof, and any combination thereof.

The pH adjustor concentration in the slurry can range from 0 to 10 wt %, while the more preferably from about 0.05 to 2 wt %, more preferably 0.1 to 1 wt %, relative to the slurry.

### Chelators

The CMP slurry of the present invention may comprise one or more of various chelators.

If no-(dissolved)-metal-containing embodiments are desired, the fluid may have chelators. Chelators can essentially trap and isolate metals having multiple oxidation states that are present in dissolved form in the fluid. If dissolved metals are in chelated form, this essentially isolates them from the substrate, which impairs their efficiency as a promoter but prevents metal ion contamination. This can extend the potlife of a slurry of oxidizer, however, and at low concentrations the chelators will not effectively impair the efficiency of the free radicals.

Small amounts of chelator is used. Chelators generally contain organic acid moieties, which can act as free radical quenchers. This could adversely affect the system performance.

Generally, less than 3 wt %, preferably less than 1 wt %, for example less than 0.5 wt % by weight of chelators are preferred.

### Stabilizers

The slurry may comprise one or more of various stabilization agents, or stabilizers.

Stabilizers can be used to extend the pot-life of the oxidizing agent(s), including compounds that produce free radicals, by isolating the activator material, by quenching free radicals, or by otherwise stabilizing the compounds that form free radicals.

Some materials are useful to stabilize hydrogen peroxide. One exception to the metal contamination is the presence of selected stabilizing metals such as tin. In some embodiments of this invention, tin can be present in small quantities, typically less than about 25 ppm, for example between about 3 and about 20 ppm. Similarly, zinc is often used as a stabilizer. In some embodiments of this invention, zinc can be present in small quantities, typically less than about 20 ppm, for example between about 1 and about 20 ppm. In another preferred embodiment the fluid slurry contacting the substrate has less than 500 ppm, for example less than 100 ppm, of dissolved metals, except for tin and zinc, having multiple oxidation states. In the most preferred commercial embodiments of this invention, the fluid slurry contacting the substrate has less than 9 ppm of dissolved metals having multiple oxidation states, for example less than 2 ppm of dissolved metals having multiple oxidation states, except for tin and zinc. In some preferred embodiments of this invention, the fluid slurry contacting the substrate has less than 50 ppm, preferably less than 20 ppm, and more preferably less than 10 ppm of dissolved total metals, except for tin and zinc.

As metals in solution are generally discouraged, it is preferred that those non-metal-containing oxidizers that are typically present in salt forms, for example persulfates, are in the acid form and/or in the ammonium salt form, such as ammonium persulfate.

Other stabilizers include free radical quenchers. As discussed, these will impair the utility of the free radicals produced. Therefore, it is preferred that if present they are present in small quantities. Most antioxidants, i.e., vitamin B, vitamin C, citric acid, and the like, are free radical quenchers. Most organic acids are free radical quenchers, but three that are effective and have other beneficial stabilizing properties are phosphonic acid, the binding agent oxalic acid, and the non-radical-scavenging sequestering agent gallic acid.

In addition, it is believed that carbonate and phosphate will bind onto the activator and hinder access of the fluid. Carbonate is particularly useful as it can be used to stabilize a slurry, but a small amount of acid can quickly remove the stabilizing ions.

Stabilization agents useful for absorbed activator can be film forming agents forming films on the silica particle.

Suitable stabilizing agents include organic acids, such as adipic acid, phthalic acid, citric acid, malonic acid, orthophthalic acid; and, phosphoric acid; substituted or unsubstituted phosphonic acids, i.e., phosphonate compounds; nitriles; and other ligands, such as those that bind the activator material and thus reduce reactions that degrade the oxidizing agent, and any combination of the foregoing agents. As used herein, an acid stabilizing agent refers to both the acid stabilizer and its conjugate base. That is, the various acid stabilizing agents may also be used in their conjugate form. By way of example, herein, an adipic acid stabilizing agent encompasses adipic acid and/or its conjugate base, a carboxylic acid stabilizing agent encompasses carboxylic acid and/or its conjugate base, carboxylate, and so on for the above mentioned acid stabilizing agents. A suitable stabilizer, used alone or in combination with one or more other stabilizers, decreases the rate at which an oxidizing agent such as hydrogen peroxide decomposes when admixed into the CMP slurry.

On the other hand, the presence of a stabilization agent in the slurry may compromise the efficacy of the activator. The amount should be adjusted to match the required stability with the lowest adverse effect on the effectiveness of the CMP system. In general, any of these optional additives should be present in an amount sufficient to substantially stabilize the slurry. The necessary amount varies depending on the particular additive selected and the particular make up of the CMP slurry, such as the nature of the surface of the abrasive component. If too little of the additive is used, the additive will have little or no effect on the stability of the slurry. On the other hand, if too much of the additive is used, the additive may contribute to the formation of undesirable foam and/or flocculant in the slurry. Generally, suitable amounts of these optional additives range from about 0.001 to about 2 weight percent relative to the slurry, and preferably from about 0.001 to about 1 weight percent. These optional additives may be added directly to the slurry or applied to the surface of the abrasive component of the slurry.

### Surfactants

The CMP slurry of the present invention may comprise one or more of various surfactants.

While there are many suitable surfactant additives for the slurry, preferred surfactant additives include dodecyl sulfate sodium salt, sodium lauryl sulfate, dodecyl sulfate ammonium salt, alcohol ethoxylate, acetylenic surfactant, and any combination thereof. Suitable commercially available surfactants include TRITON DF 16™ manufactured by Dow Chemicals and various surfactants in SUIRFYNOL™, DYNOL™, Zetasperse™, Nonidet™, and Tomadol™ surfactant families, manufactured by Air Products and Chemicals.

Various anionic, cationic, nonionic and zwitterionic surfactants having molecular weight in the range from less than 1000 to greater than 30,000 are contemplated as dispersants. Included are sodium, potassium, or preferably ammonia salts of stearate, lauryl sulfate, alkyl polyphosphate, dodecyl benzene sulfonate, disopropylnaphthalene sulfonate, dioctylsulfosuccinate, ethoxylated and sulfated lauryl alcohol, and ethoxylated and sulfated alkyl phenol.

Various cationic surfactants include polyethyleneimine, ethoxylated fatty amine and stearylbenzyldimethylammonium chloride or nitrate. Alternate dispersants contemplated in the present invention include: polyethylene glycols, lecithin, polyvinyl pyrrolidone, polyoxyethylene, isoctylphenyl ether, polyoxyethylene nonylphenyl ether, amine salts of alkylaryl sulfonates, polyacrylate and related salts, polymethacrylate.

If a surfactant is added to the first CMP slurry, then it may be an anionic, cationic, nonionic, or amphoteric surfactant or a combination of two or more surfactants can be employed. Furthermore, it has been found that the addition of a surfactant may be useful to reduce the within-wafer-non-uniformity (WIWNU) of the wafers, thereby improving the surface of the wafer and reducing wafer defects.

In general, the amount of additive such as a surfactant that may be used in the first CMP slurry should be sufficient to achieve effective stabilization of the slurry and will typically vary depending on the particular surfactant selected and the nature of the surface of the metal oxide abrasive. For example, if not enough of a selected surfactant is used, it will have little or no effect on first CMP slurry stabilization. On the other hand, too much surfactant in the CMP slurry may result in undesirable foaming and/or flocculation in the slurry. As a result, stabilizers such as surfactants should generally be present in the slurry of this invention in an amount ranging from about 0.001% to about 0.2% by weight, and preferably from about 0.001 to about 0.1 weight percent. Furthermore, the additive may be added directly to the slurry or treated onto the surface of the metal oxide abrasive utilizing known techniques. In either case, the amount of additive is adjusted to achieve the desired concentration in the first polishing slurry.

### Corrosion Inhibitors

While CMP slurries in present invention greatly reduce need for use of any corrosion inhibitors, CMP slurries may comprise one or more various corrosion inhibitors for certain highly challenging applications.

Corrosion inhibitor can be a film forming agent or it can act by any other mechanisms such as cathodic inhibition, controlling reactions associated with hydroxyl radicals, etc.

Suitable corrosion inhibitors include, but are not limited to, nitrogen containing heterocycles without N—H bonds, sulfides, oxazolidines or mixtures. Specific inhibitors claimed 4ethyl-2oxazoline 4-methanol, 2-3,5 trimethyl pyrazine, 2-ethyl 3-5 dimethyl pyrazine, glutathione, thiophene, mercapto pyridine n-oxide, thiamine hypochloride, tetraethyl thiruam disulfide, polyethyleneimine, cyanate compounds, alkylammonium ions or amino acids (other than those containing S groups), aminopropyl silanol, aminopropylsiloxane. There are corrosion inhibitors, taught in various patents e.g. U.S. Pat. No. 6,083,419, U.S. Pat. No. 6,136,711, U.S. Pat. No. 7,247,567, and U.S. Pat. No. 7,582,127, the disclosures of which are hereby incorporated by reference in their entireties.

### Removal Rate Selectivity Adjustors

Different applications require different CMP removal rate selectivity between tungsten and the barrier films or tungsten and dielectric films. Various chemical additives may be used to control the barrier and the dielectric removal rates to ach]ieve desired selectivity.

The dielectric film can be any suitable dielectric material having a dielectric constant of about 4 or less. Typically the dielectric layer is a silicon-containing material, for example, silicon dioxide or oxidized silicon dioxides like carbon-doped silicon dioxide and aluminosilicates. The dielectric layer also can be a porous metal oxide, glass, organic polymer, fluorinated organic polymer, or any other suitable high or low-κ dielectric layer. The dielectric layer preferably comprises silicon oxide such as TEOS, silicon nitride, silicon oxynitride, silicon carbide, aluminum oxide, or a material with a dielectric constant of about 3.5 or less.

The examples of such additives include but are not limited to polymers such as polyvinyl alcohol, polyvinyl pyrrolidone, poly methyl methacrylate, polyethyleneimine, polyformaldehyde, polyethylene oxide, polyethylene oxide and polymethacrylic acid., various organic acids such as citric acid, pthalic acid, siloxane compounds etc. Various surfactants may also be useful for lowering the dielectric removal rates.

### WORKING EXAMPLE

### General Experimental Procedure

In the examples presented below, experiments were run using the procedures and experimental conditions given below.

Parameters:

Å: angstrom(s)—a unit of length

BP: back pressure, in psi units

CMP: chemical mechanical planarization=chemical mechanical polishing

CS: carrier speed

DF: Down force: pressure applied during CMP, units psi

min: minute(s)

ml: milliliter(s)

mV: millivolt(s)

psi: pounds per square inch

PS: platen rotational speed of polishing tool, in rpm (revolution(s) per minute)

SF: polishing composition flow, ml/min

Removal Rates and Selectivity

Removal Rate(RR)=(film thickness before polishing−film thickness after polishing)/polish time.

All percentages are weight percentages unless otherwise indicated.

Etch rate testing was performed on silicon wafer coupons coated with tungsten films. The thickness of the tungsten film etched was determined by four point probe resistivity measurement technique before and after etching. Etching was carried out by dipping the coupons in the slurry solutions at 40° C.

The CMP tool that was used in the examples was a Mirra®, manufactured by Applied Materials, 3050 Boweres Avenue, Santa Clara, Calif., 95054. The polishing was performed on IC1010™ CMP pad from Dow Chemicals at 3.5 psi membrane pressure, 127 RMP table speed and 97 ml/min slurry flow rate. Tungsten removal rates were measured using sheet resistance measurement techniques.

Working slurries comprised of colloidal silica abrasive particles, iron acetate coated silica particle, pH adjustor and water. The pH of the slurries ranged from 2.5 to 9. The silica particle concentration ranged between 0-30 wt %, or between 0.05-10 wt % or between 0.1 and 2 wt %. The activator particle concentration ranged from 0.001 to 2 wt % or between 0.01 to 1 wt % or between 0.05 to 0.5 wt %. The slurry could be made 10× concentrated. It was then diluted with 9 times with water. Hydrogen peroxide was added in concentrations ranging from 0.01-30 wt %.

### Example 1

A stock slurry solution with pH 7 was prepared with following composition as shown in Table I.

The abrasive used in the slurry was colloidal silica with average particle size around 160 nm.

TABLE I
Stock Slurry

| | wt % |
|---|---|
| Fe coated silica particles | 1.7 |
| Colloidal Silica | 5 |
| Preservative (Neolone M-10) | 0.015 |
| Potassium hydroxide | 0.11 |
| Water | 93.285 |

Activator-containing particles used in the slurry was Fe coated silicon particles comprised of a colloidal silica particles (˜50 nm) coated with iron acetate. The total iron content measured in the slurry was 153 ppm. Activator-containing particles such as iron acetate coated silica sol, can be made by a process similar to one in U.S. Pat. No. 4,478,742, the disclosure of which is hereby incorporated by reference in its entireties.

The stock slurry was diluted with DI water with ratio of 9 parts water to 1 part of slurry. Hydrogen peroxide was added to yield a concentration of 4 wt % in the diluted form. Small amounts of nitric acid and potassium hydroxide (just to Slurry #5) were added to adjust the pH.

Table II below provided the composition information about these dilutions.

TABLE II
Working Slurries

| | | | | | Hydrogen | |
|---|---|---|---|---|---|---|
| | | Stock | Nitric acid | KOH | Peroxide | |
| Slurry | DI Water | Slurry | (5 wt %) | (10 wt %) | (30%) | |
| # | (gm) | (gm) | (gm) | (gm) | (gm) | pH |
| 1 | 623 | 69 | 0.74 | | 106.67 | 4.71 |
| 2 | 624 | 69 | 0.36 | | 106.67 | 5.22 |
| 3 | 624 | 69 | 0.14 | | 106.67 | 5.53 |
| 4 | 624 | 69 | 0.01 | | 106.67 | 6.01 |
| 5 | 624 | 69 | 0.06 | 0.04 | 106.67 | 6.48 |

### Example 2

Etch rate testing was performed on silicon wafer coupons coated with tungsten films. The results were shown in Table III

Polishing tests were also carried out using 200 mm silicon wafers coated with tungsten films. Tungsten removal rates were measured using sheet resistance measurement techniques. The polishing results were also shown in Table III

TABLE III

| | CMP Removal Rate | Static Etch Rate |
|---|---|---|
| | (Å/min) | (Å/min) |
| 4.7 | 6363 | 172 |
| 5.2 | 6289 | 113 |
| 5.5 | 6293 | 126 |
| 6 | 6368 | 80 |
| 6.5 | 6258 | 66 |

The results have shown that there was great decrease in static etch rate with the increase in pH of the CMP slurries. The CMP removal rates, on the other hand were not affected by pH change in the specified pH range. As a result, near neutral pH has offered a significant improvement in CMP removal rate to static etch rate, which might have impact on improving planarization and reducing corrosion defects.

### Example 3

Following slurries were made and shown in Table IV. The activator containing particles and the colloidal silica particles were the same to those used in example 1.

These slurries were used to polish wafers with tungsten, titanium nitride (TiN) and TEOS films. The polishing was performed using IC1010™ CMP pad from Dow Chemicals at 4.2 psi membrane pressure, 127 RMP table speed and 90 ml/min slurry flow rate.

TABLE IV

| | wt % | | | |
|---|---|---|---|---|
| Fe coated silica particles | 0.26 | 0.26 | 0.26 | 0.26 |
| Colloidal Silica | 0.5 | 0.5 | 0.5 | 0.5 |
| Hydrogen peroxide | 3 | 3 | 3 | 3 |
| pH Adjustor | Nitric | KOH | KOH | KOH |
| | acid | | | |
| Water | Balance | Balance | Balance | Balance |
| Final pH | 2.5 | 4.5 | 7 | 9 |

Static etch rate measurements were also performed using these slurries by dipping the wafers with tungsten films in the slurries for 5 minutes at 40° C. while the slurry was being stirred.

The removal rates during CMP for different films and static etch rates for tungsten films were summarized below in Table V.

TABLE V

| | W | TEOS | TiN | | |
|---|---|---|---|---|---|
| | Removal | Removal | Removal | W/TEOS | W Etch |
| Slurry | Rate | Rate | Rate | Removal | Rates |
| pH | (Å/min) | (Å/min) | (Å/min) | Selectivity | (Å/min) |
| 2.5 | 5953 | 124 | 1808 | 48 | 1254 |
| 4.5 | 6244 | 29 | 1311 | 215 | 139 |
| 7 | 6335 | 53 | 1225 | 121 | 55 |
| 9 | 6445 | 36 | 1182 | 179 | 46 |

The results have shown that unexpectedly the tungsten etch rate reduced from a very high value (1254 Å/min) at pH 2.5 to a low value at pH≧4.5 (139 Å/min).

Additionally there was a drastic reduction in CMP removal rates for TEOS films enabling high (>100) W/TEOS removal selectivity (defined as the Removal Rate of W divided by the Removal Rate of TEOS). This high removal selectivity is highly desired in tungsten CMP slurries.

### Example 4

Slurries were made with following compositions as shown in Table VI.

These slurries were used to polish patterned wafers with tungsten filled line structures. These wafers were patterned with MIT/Sematech 854 mask. Wafers were polished at 3 psi membrane pressure, 113 RPM table speed, 111 RPM head speed and 90 ml/min slurry flow rate. These wafers were polished at 50% overpolish using end-point measurement system. Topography was measured on different line structures on the patterned wafers using profilometer.

TABLE VI

| | wt % | |
|---|---|---|
| Fe coated silica particles | 0.17 | 0.17 |
| Colloidal Silica | 0.5 | 0.5 |
| Hydrogen peroxide | 3 | 3 |
| pH Adjustor | Nitric | KOH |
| | acid | |
| Water | Balance | Balance |
| Final pH | 2.5 | 7 |

The erosion topography (Angstroms) measured on various line structures with 50% pattern density was summarized below in Table VII.

TABLE VII

| | | pH 2.5 | pH 7 |
|---|---|---|---|
| 0.25/0.25 | Microns | 894 | 672 |
| 2/2 | Microns | 852 | 618 |
| 5/5 | Microns | 728 | 554 |
| 10/10 | Microns | 614 | 494 |

The dishing topography (Angstroms) on these line structures was summarized below in Table VIII.

TABLE VIII

| | | pH 2.5 | pH 7 |
|---|---|---|---|
| 0.25/0.25 | Microns | 471 | 293 |
| 2/2 | Microns | 675 | 634 |
| 5/5 | Microns | 1020 | 881 |
| 10/10 | Microns | 1717 | 1451 |

Tables VII and VIII have shown that the CMP slurries having pH 7 demonstrated substantial improvement in both dishing and erosion compared to acidic pH slurries.

The mechanism by which better corrosion protection is achieved at neutral pH compared to acidic pH is not yet thoroughly studied. While not bound by any theory, it is believed that the surface chemical of heterogeneous activator with pH may be playing crucial role.

The embodiments and working examples of present invention listed above, are exemplary of numerous embodiments and working examples that may be made of present invention. It is contemplated that numerous other configurations of the process may be used, and the materials used in the process may be elected from numerous materials other than those specifically disclosed.

1. A tungsten chemical mechanical planarization (CMP) slurry comprising:
0.0 wt % to 30 wt % abrasive;
0.01 wt % to 5 wt % activator-containing particles;
peroxygen oxidizer;
0 to 10 wt % pH adjustor; and
the remaining being water;
wherein the tungsten CMP slurry has a pH in the range of 4 to 10.

2. The CMP slurry of claim 1, wherein the abrasive is selected from the group consisting of fumed silica, colloidal silica, alumina, gamma alumina, ceria, abrasive plastic or polymeric particles, spinels, zinc oxide, hybrid organic/inorganic particle, coated abrasive particles comprising of a core and a shell made up of different materials wherein the shell may be continuous or discontinuous, and combinations thereof.

3. The CMP slurry of claim 1, wherein the activator-containing particles are particles containing activators; wherein
the particles are selected from the group consisting of silica, alumina, zirconium oxide, ceria, polymers, mixed oxide particles, ceria coated silica particles, aluminum doped silica particles, and combinations thereof; and
the activators are metal-containing compounds having a metal selected from periodic table groups 1(b), 2(b), 3(b), 4(b), 5(b), 6(b), 7(b), and 8(b).

4. The CMP slurry of claim 1, wherein the pH adjustor is selected from the group consisting of acid, base, amine, and combinations thereof.

5. The CMP slurry of claim 1 further comprises at least one additive selected from the group consisting of promoters, chelating agents, corrosion inhibitors, organic and/or inorganic acids, pH buffers, oxidizer stabilizers, passivating agents, surfactants, dispersants, polymers, biological preservatives, removal rate selectivity adjustors, film-forming anticorrosion agents, and polish enhancement agents.

6. The CMP slurry of claim 1 comprises the abrasive selected from the group consisting of fumed silica, colloidal silica, and combinations thereof; the activator-containing particles comprise metal coated silica particles, wherein the metal is selected from the group consisting of iron, copper, cerium, nickel, manganese, cobalt, and combinations; the pH adjustor selected from the group consisting of ammonium hydroxide, nitric acid, phosphoric acid, sulfuric acid, and combinations thereof; and the pH is 5-9.

7. A method for chemical mechanical planarization of a semiconductor substrate comprising at least one surface having tungsten, comprising the steps of:
contacting tungsten with a polishing pad;
delivering a polishing slurry to the at least one surface having tungsten, the polishing slurry comprising:
i. 0.0 wt % to 30 wt % abrasive;
ii. 0.01 to 5 wt % activator-containing particles;
iii. peroxygen oxidizer;
iv. 0 to 10 wt % pH adjustor; and
v. the remaining being water;
wherein the polishing slurry has a pH in the range of 4 to 10;
and
polishing the at least one surface having tungsten with the polishing slurry.

8. The method of claim 7, wherein the abrasive is selected from the group consisting of fumed silica, colloidal silica, alumina, gamma alumina, ceria, abrasive plastic or polymeric particles, spinels, zinc oxide, hybrid organic/inorganic particle, coated abrasive particles comprising of a core and a shell made up of different materials wherein the shell may be continuous or discontinuous, and combinations thereof.

9. The method of claim 7, wherein the activator-containing particles are particles containing activators; wherein
the particles are selected from the group consisting of silica, alumina, zirconium oxide, ceria, polymers, mixed oxide particles, ceria coated silica particles, aluminum doped silica particles, and combinations thereof; and
the activators are metal-containing compounds having a metal selected from periodic table groups 1(b), 2(b), 3(b), 4(b), 5(b), 6(b), 7(b), and 8(b).

10. The method of claim 7, wherein the pH adjustor is selected from the group consisting of acid, base, amine, and combinations thereof.

11. The method of claim 7, wherein the polishing slurry further comprises at least one additive selected from the group consisting of promoters, chelating agents, corrosion inhibitors, organic and/or inorganic acids, pH buffers, oxidizer stabilizers, passivating agents, surfactants, dispersants, polymers, biological preservatives, removal rate selectivity adjustors, film-forming anticorrosion agents, and polish enhancement agents.

12. The method of claim 7, wherein the polishing slurry comprises the abrasive selected from the group consisting of fumed silica, colloidal silica, and combinations thereof; the activator-containing particles comprise metal coated silica particles, wherein the metal is selected from the group consisting of iron, copper, cerium, nickel, manganese, cobalt, and combinations; the pH adjustor selected from the group consisting of ammonium hydroxide, nitric acid, phosphoric acid, sulfuric acid, and combinations thereof; and the pH is 5-9.

13. The method of claim 7, wherein the semiconductor substrate further comprises at least one surface having a dielectric material, and the method further comprising the steps of:
contacting the dielectric material with a polishing pad;
delivering the polishing slurry to the at least one surface having the dielectric material; and
polishing the at least one surface having dielectric material with the polishing slurry;
wherein a W/dielectric material Removal Selectivity is >100.

14. The method of claim 13, wherein the polishing slurry comprises the abrasive selected from the group consisting of fumed silica, colloidal silica, and combinations thereof; the activator-containing particles comprise metal coated silica particles, wherein the metal is selected from the group consisting of iron, copper, cerium, nickel, manganese, cobalt, and combinations; the pH adjustor selected from the group consisting of ammonium hydroxide, nitric acid, phosphoric acid, sulfuric acid, and combinations thereof; the dielectric material is TEOS, and the pH is 5-9.

15. A system for chemical mechanical planarization (CMP), comprising:
a. a semiconductor substrate comprising at least one surface having tungsten;
b. a polishing pad; and
c. a polishing slurry comprising:
i. 0.0 wt % to 30 wt % abrasive;
ii. 0.01 to 5 wt % activator-containing particles;
iii. peroxygen oxidizer;
iv. 0 to 10 wt % pH adjustor; and
v. the remaining being water;
wherein the polishing slurry has a pH in the range of 4 to 10;
and
wherein the at least one surface having tungsten is in contact with the polishing pad and the polishing slurry.

16. The system of claim 15, wherein the abrasive is selected from the group consisting of fumed silica, colloidal silica, alumina, gamma alumina, ceria, abrasive plastic or polymeric particles, spinels, zinc oxide, hybrid organic/inorganic particle, coated abrasive particles comprising of a core and a shell made up of different materials wherein the shell may be continuous or discontinuous, and combinations thereof.

17. The system of claim 15, wherein the activator-containing particles are particles containing activators; wherein
the particles are selected from the group consisting of silica, alumina, zirconium oxide, ceria, polymers, mixed oxide particles, ceria coated silica particles, aluminum doped silica particles, and combinations thereof; and
the activators are metal-containing compounds having a metal selected from periodic table groups 1(b), 2(b), 3(b), 4(b), 5(b), 6(b), 7(b), and 8(b).

18. The system of claim 15, wherein the pH adjustor is selected from the group consisting of acid, base, amine, and combinations thereof.

19. The system of claim 15, wherein the polishing slurry further comprises at least one additive selected from the group consisting of promoters, chelating agents, corrosion inhibitors, organic and/or inorganic acids, pH buffers, oxidizer stabilizers, passivating agents, surfactants, dispersants, polymers, biological preservatives, removal rate selectivity adjustors, film-forming anticorrosion agents, and polish enhancement agents.

20. The system of claim 15, wherein the polishing slurry comprises the abrasive selected from the group consisting of fumed silica, colloidal silica, and combinations thereof; the activator-containing particles comprise metal coated silica particles, wherein the metal is selected from the group consisting of iron, copper, cerium, nickel, manganese, cobalt, and combinations; the pH adjustor selected from the group consisting of ammonium hydroxide, nitric acid, phosphoric acid, sulfuric acid, and combinations thereof; and the pH is 5-9.

21. The system of claim 19, wherein the semiconductor substrate further comprises at least one surface having a dielectric material, and the at least one surface having the dielectric material is in contact with the polishing pad and the polishing slurry; and
wherein the system provides a W/dielectric material Removal Selectivity>100.

22. The system of claim 21, wherein the polishing slurry comprises the abrasive selected from the group consisting of fumed silica, colloidal silica, and combinations thereof; the metal coated silica particles, wherein the metal is selected from the group consisting of iron, copper, cerium, nickel, manganese, cobalt, and combinations; the pH adjustor selected from the group consisting of ammonium hydroxide, nitric acid, phosphoric acid, sulfuric acid, and combinations thereof; the dielectric material is TEOS, and the pH is 5-9.
